(19) United States
(12) Patent Application Publication
(10) Pub. No.: US 2018/0260929 A1
(43) Pub. Date: Sep. 13, 2018

(54) DIGITAL CAMERA METHODS AND DEVICES OPTIMIZED FOR COMPUTER VISION APPLICATIONS

(71) Applicant: Intel Corporation, Santa Clara, CA (US)

(72) Inventor: Andrey Vladimirovich Belogolovy, Hillsboro, OR (US)

(21) Appl. No.: 15/453,596

(22) Filed: Mar. 8, 2017

(51) Int. Cl. G06T 1/20; H04N 5/33; H04N 5/225; H04N 5/265; H04N 9/04; H04N 5/357; H04N 5/232; H01L 27/146

(52) U.S. Cl. CPC G06T 1/20; H04N 5/332; H04N 5/2256; H04N 5/265; H01L 27/14643; H04N 5/357; H04N 5/23267; H01L 27/14621; H04N 9/045

(57) ABSTRACT

Disclosed in some examples are improvements to digital camera technology to capture and process images for better use in computer vision applications. For example, improved color filters, camera lens placements, and image processing pipelines.

### TECHNICAL FIELD

Embodiments pertain to improvements in digital camera devices to produce better images for computerized vision applications. Some embodiments relate to improved camera devices including a multi-position camera and an improved image sensor filter. Other embodiments relate to improved image processing pipelines.

### BACKGROUND

Image capture devices such as digital still and video cameras (referred to herein collectively as digital cameras) are utilized by computer vision applications such as autonomous cars, face recognition, image search, machine vision, optical character recognition, remote sensing, robotics, and the like. These digital cameras utilize image sensors such as a Charge Coupled Device (CCD) and Active Pixel Sensors (APS)—commonly known as Complementary Metal Oxide Semiconductors (CMOS) to convert detected light wavelengths to electrical signals in the form of data.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 shows a diagram of a digital camera device according to some examples of the present disclosure.

FIG. 2 shows a diagram of the field of view of the various lenses of camera device of FIG. 1 at the focal point according to some examples of the present disclosure.

FIG. 3 shows color filter arrays (CFA) according to some examples of the present disclosure.

FIG. 4 shows a block diagram of components of an example digital camera according to some examples of the present disclosure.

FIG. 5 shows a block diagram of an example imaging pipeline according to some examples of the present disclosure.

FIG. 6 shows a block diagram of an example CV optimized imaging pipeline according to some examples of the present disclosure.

FIG. 7 shows a flowchart of an example method of the processor performing the image processing pipeline of FIG. 6.

FIG. 8 shows a flowchart of a method of capturing an image according to some examples of the present disclosure.

FIG. 9 shows a flowchart of a method of capturing an image according to some examples of the present disclosure.

FIG. 10 is a block diagram illustrating an example of a machine upon which one or more embodiments may be implemented.

### DETAILED DESCRIPTION

Computer vision (CV) is a field that includes methods for acquiring, processing, analyzing, and understanding images in order to produce numerical or symbolic information, e.g., in the form of decisions. CV has become a part of many application areas for wearables and Internet of Things (IoT) devices such as human safety, navigation, and augmented reality. For example, autonomous cars may utilize CV to provide for object detection, identification, and tracking. The starting point of every CV application is a camera that provides inputs to the rest of a processing chain (e.g., detection, tracking, recognition, and the like). In CV, the quality of the input significantly affects the performance. If the input is ‘bad’ the output will also be ‘bad.’

Most cameras that are used today in CV were originally developed for human vision or human reception and not for CV. CV algorithms look at an image differently than human eyes. For example, to a human eye, sharp edges are undesirable so digital camera image processing pipelines (e.g., post processing operations performed on the raw data from the image sensor) try to smooth these sharp edges. For CV, sharp edges are desired to detect edges and most CV applications do edge detection as a first step (which is the reverse of the image smoothing of the image pipeline). Thus, smoothing the sharp edges in a camera's image processing pipeline is counter-productive for CV applications. Color balance adjustments are similar in that adjustments done for human vision are undone or are undesirable by CV applications.

In addition, cameras optimized for human vision capture only visible light (Red. Green. and Blue components) due to filters applied after the lens and before the sensor. For computer vision applications, useful data may be in the Ultra Violet (UV) and Infra-Red (IR) spectrums. Blue wavelengths are less important for CV applications as most images have blue components due to the interaction between light and the oxygen in our atmosphere. As a result, the blue information is less important.

Finally, the lens viewing angle and sensor resolutions of most cameras do not provide enough pixels for complex CV applications. For CV applications there are often minimum pixel size requirements in pixels that can be processed. If the number of pixels of an object are less than the requirements, the accuracy of the CV applications is reduced. For example, for pedestrian detection, the width of a “pedestrian” in pixels might be required to be greater than 64 pixels for various CV algorithms. If an object is less than 64 pixels, the object may not be recognized as a pedestrian. As another example, consider facial detection: if the object is less than 32 pixels it may not be detected as a face. Because of the flat viewing angle, objects may only be detected when they are very close to the camera.

Disclosed in some examples are systems, methods, camera devices, and machine readable mediums that overcome these deficiencies. In some examples, a camera device is disclosed which provides for a plurality of lenses with each lens having at least a portion of its field of view at a focal point overlapping with a portion of a field of view at the focal point with at least one other lens. In some examples, the camera device provides for a plurality of lenses with each lens having at least a portion of its field of view at a focal point overlapping with a portion of a field of view at the focal point with 2, 3, 4, 5, or more other lenses depending on the configuration.

For example, in some configurations, at least two rows and at least two columns of lenses are disclosed wherein each lens has partially overlapping fields of views to at least three other lenses. Each lens may correspond to a unique image sensor, or may correspond to a particular section of an image sensor. In embodiments in which each lens corresponds to a unique image sensor, the plurality of images may be stitched together to form a larger image. The overlapping fields of views assists in stitching the image together and may provide additional depth information to determine a three dimensional depth of the image. Additionally, in some examples, the lenses may be mounted on a curved face providing a wider field of view than other multi-camera systems. This camera system may provide for a wider field of vision and the lenses may be optimized for the desired focal length such that any objects that are to be identified by CV applications appear at a proper size for detection. For example, by the use of many image sensors.

Also disclosed in some examples are optimized color filter arrays (CFA)s (such as Bayer filters) that provide for one or both of ultraviolet (UV) and infra-red (IR) light to contact the image sensor at one or more pixel positions of the imaging sensor to generate UV and/or IR data. Traditional color filters filter out all light but Red, Green. and Blue light respectively in each position of a matrix filter over the image sensor. The additional information on the UV or IR spectrums may help CV applications in object detection. For example, IR data indicates heat and can be used to identify objects that are warmer than the ambient atmosphere (such as a person or animal).

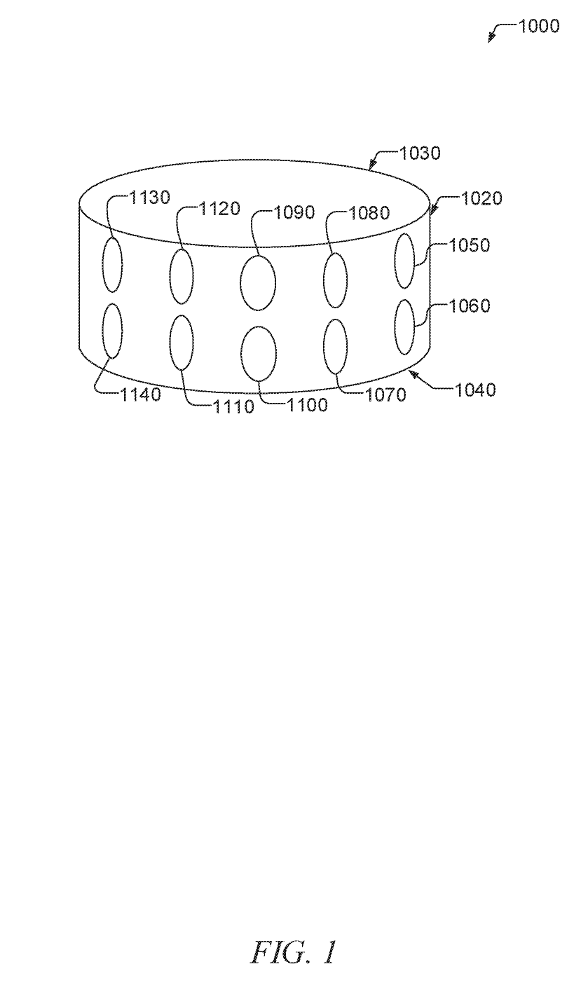

Also disclosed in other examples are streamlined image processing pipelines that process data in ways that are better for CV analysis. In some examples, traditional image processing blocks are bypassed, or are able to be bypassed. For example, the particular image processing blocks to apply in a given instance are configurable. In other examples, new image processing pipelines and functions may be introduced specific to CV applications. For example, noise suppression, color correction, and compression blocks are removed or bypassed. In some examples in which multiple sensors are utilized (e.g., the disclosed camera device—see FIG. 1) one exposure determination algorithm may be utilized across all sensors in the device to provide the same exposure values across all of them. In other examples in which multiple sensors are utilized, a geometrical distortion compensation block may be utilized which compensates for distortion to an object caused by slightly different viewing angles and camera mounting positions. In yet other examples, an image stitching block may be utilized for stitching together images from multiple sensors, a stabilization block for stabilizing multiple images, and the like. In still more examples, a Histogram of Gradients (HOG), Harris Corner, and other blocks may be utilized.

It will be appreciated that one or more of these improvements (e.g., the camera device, CFA filters, and imaging pipelines) may be utilized independently or combined. For example, the camera device of FIG. 1 may be utilized with one or both of the CFA filter and enhanced CV image pipeline. As another example, the CFA filter may be utilized in a single lens camera, optionally with the enhanced CV image pipelines. As another example the enhanced CV image pipelines may replace or be used as an alternative to the normal image pipeline of a normal digital camera, or may be used with the enhanced CFA, or the enhanced camera device of FIG. 1. As used herein, the disclosed improvements may be utilized on still, video, or combination still and video digital camera devices.

Turning now to FIG. 1, an image capture device in the form of a digital camera device 1000 is shown. Digital camera device 1000 may be a still, video, or combination still and video camera. Lens mounting surface 1020 is disposed between top surface 1030 and bottom surface 1040. As shown in FIG. 1, the lens mounting surface 1020 is curved and the digital camera device 1000 is cylindrical in shape. In some examples, the lens mounting surface 1020 may be flat. In some examples, the surface in back of the device (not shown) opposite of the lens mounting surface 1020 may be flat (that is, the digital camera device 1000 may only be curved on the front—lens mounting surface 1020 surface). Lenses 1050, 1060, 1070, 1080, 1090, 1100, 1110, 1120, 1130, and 1140—as shown—are arranged in two rows and 5 columns. In some examples, greater or fewer lenses may be utilized as previously discussed. For example, two rows and two columns, three rows and two columns, three rows and three columns, and the like.

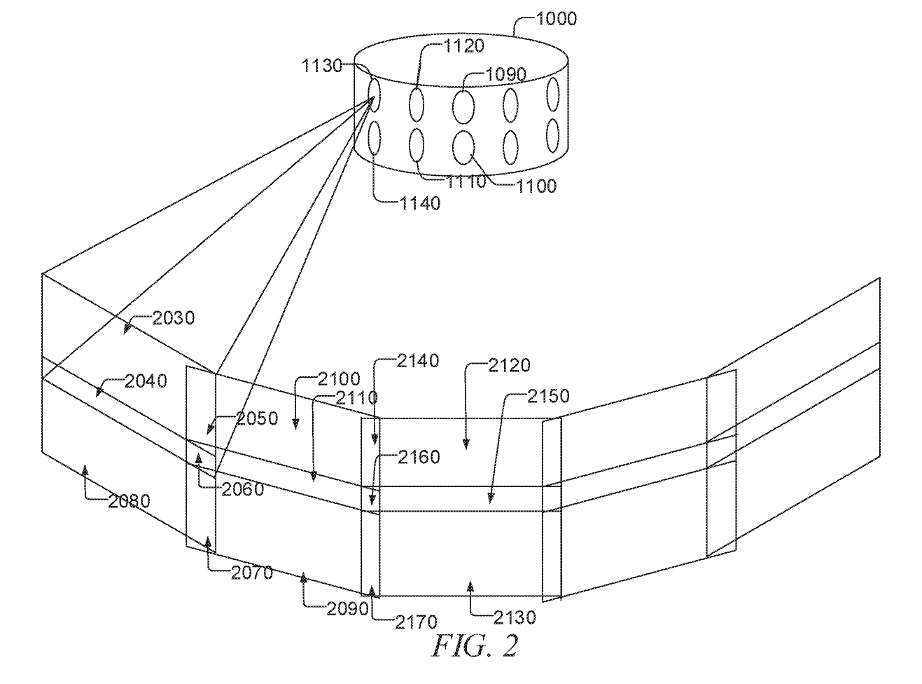

Turning now to FIG. 2, a diagram of the field of view of the various lenses of camera device 1000 at a focal point is shown according to some examples of the present disclosure. Lens 1130 has field of vision represented by square image 2030 at a desired focal length. Lens 1140 has field of vision represented by square image 2080. Area of overlap 2040 is an area of square image 2030 and square image 2080 where the field of view of lenses 1130 and 1140 at least partially overlap. Similarly, lens 1120 has field of vision represented by square image 2100 and lens 1110 has field of vision represented by square image 2090. Overlap area 2110 is an area of square image 2090 and 2100 where the field of view of lenses 1110 and 1120 overlap. Additionally overlap area 2070 is an area of square images 2090 and 2080 where the field of view of lenses 1110 and 1140 overlap. Overlap area 2050 is an area of square images 2100 and 2030 where the field of view of lenses 1130 and 1120 overlap. Area 2060 is an area of square images 2030, 2080, 2100, and 2090 where the field of view of lenses 1110, 1120, 1130, and 1140 overlap. While square fields of view are utilized to diagram the overlapping coverage of the lenses, one of ordinary skill in the art will appreciate that rectangular fields of view, circular fields of view, and other shapes may be utilized.

Lens 1090 has a field of vision at the focal point represented by square image 2120, lens 1100 has a field of vision represented by square image 2130. Area of overlap 2150 is an area of square images 2120 and 2130 where the field of view of lenses 1090 and 1100 overlap. Area of overlap 2140 is an area of square images 2120 and 2100 where the field of view of lenses 1090 and 1120 overlap. Area of overlap 2170 is an area of square images 2130 and 2090 where the field of view of lenses 1110 and 1100 overlap. Area of overlap 2160 is an area of square images 2120, 2130, 2090, and 2100 where the field of view of lenses 1110, 1100, 1120, and 1090 overlap. It will be appreciated that the number of overlapping fields of view may vary and that the amount of overlap (in terms of pixels) may be configurable and may vary.

Thus, in the example device of FIG. 1, a particular lens may have one or more areas of overlap in their field of view with one or more other lenses. In the example of FIG. 1, all lenses have at least three areas of overlap, with some lenses in the interior columns having five areas of overlap. For example, lens 1120 shares overlapping fields of view with lenses 1110, 1090, 1100, 1140, and 1130. As can be appreciated, the field of view overlaps may be adjusted by adjusting the angles of the lenses with respect to each other at the desired focal point. For example, the angles may be adjusted to provide only two areas of overlap for a particular lens.

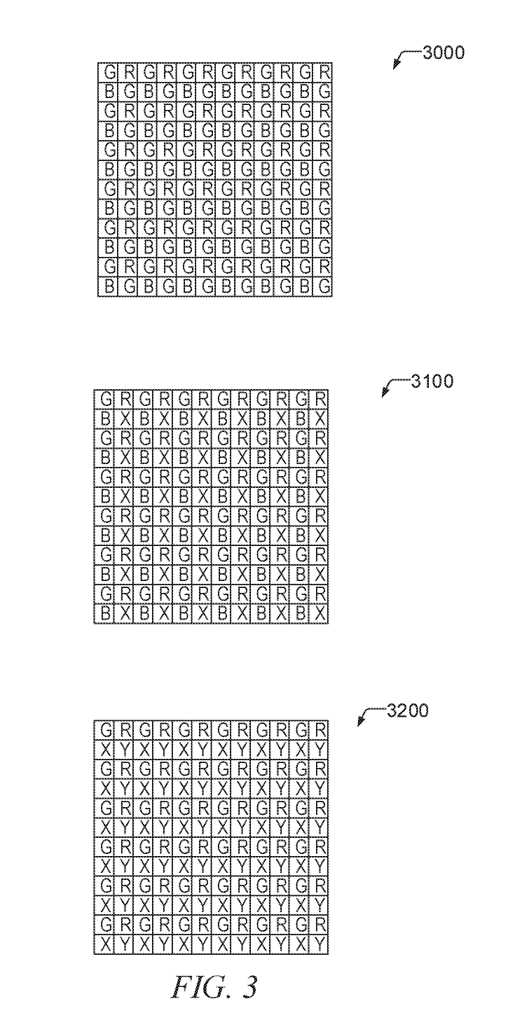

Turning now to FIG. 3, color filter arrays (CFA) 3000, 3100, and 3200 are shown according to some examples of the present disclosure. To achieve color information, an image sensor is typically covered by a CFA which is a grid array of tiny color filters (e.g., elements) placed over the pixel sensors of an image sensor to capture color information. The color filters filter out all (or substantially all) wavelengths but the desired wavelength. The CFA is needed because photosensors typically only detect light intensity but do not detect wavelength information. By filtering out all information but a particular wavelength, the sensor is able to determine an intensity of the particular wavelength that is let through the filter—thus producing color information. For traditional human vision oriented cameras, these filters are made up of red (R), green (G), and blue (B) filters in a repeating grid pattern, for example, as shown with respect to CFA 3000 (that allows only red, green, and blue light—or substantially red, green and blue light through, for example).

As already noted, UV and IR wavelength intensity information may be useful in CV applications. In CFA 3100 the G filter in every other row of the CFA is replaced with an “X”. The X could either be a filter that filters out all light except UV light or a filter that filters out all light except IR light. UV light is typically wavelengths in the 10-400 nanometer range while IR is typically wavelengths in the 700 nm-1 mm range. In CFA 3200, the blue filter is replaced as blue intensity information is less important for CV applications. The blue filter may be replaced with both a UV and IR filter (denoted X and Y—in either order). By R, G, B, UV, IR filter it is meant that light outside these wavelengths are filtered out leaving only that particular component (e.g., the R filter filters out substantially all other wavelengths other than Red wavelengths). One of ordinary skill in the art with the benefit of this disclosure will appreciate that other organizations of the various filters are possible and within the scope of the present disclosure. For example, both X and Y may be UV filters. Similarly, both X and Y may be IR filters. The IR and UV CFAs disclosed in FIG. 3 may be utilized in the camera device of FIGS. 1 and 2 or may be utilized in other digital cameras.

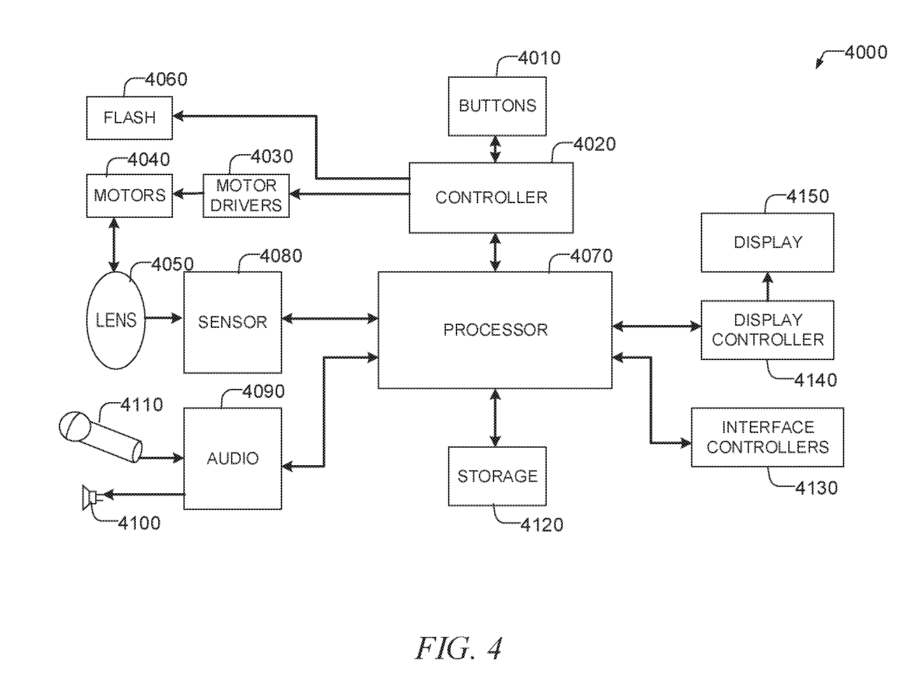

FIG. 4 shows a block diagram of components of an example digital camera 4000 according to some examples of the present disclosure. Digital camera 4000 may be either a still digital camera, a video digital camera, or have the ability to take both still frames and videos. In some examples, buttons or other user inputs 4010 and one or more user outputs (e.g., LED status lights (not shown)) and sensors (light sensors) are sensed and managed by a controller 4020. Example buttons 4010 may include lens control buttons, shutter control buttons, exposure control buttons and the like. Controller 4020 controls motor drivers 4030 which drives motors 4040 which adjusts the lens 4050. Additionally the controller 4020 may activate the flash 4060 or other lighting sources based upon user defined settings and in some examples the ambient lighting conditions (as detected by the light sensor). Controller 4020 communicates with (and takes instructions from) the processor 4070. Light enters the lens and strikes the sensor 4080 (after being filtered out by a CFA) on one or more pixels. The data is then sent to the processor 4070. Audio input (e.g., from a microphone) 4110 is received by an audio controller 4090 and sent to processor 4070. Audio output is sent from processor 4070 to audio controller 4090 and output to an audio output 4100 (e.g., speaker).

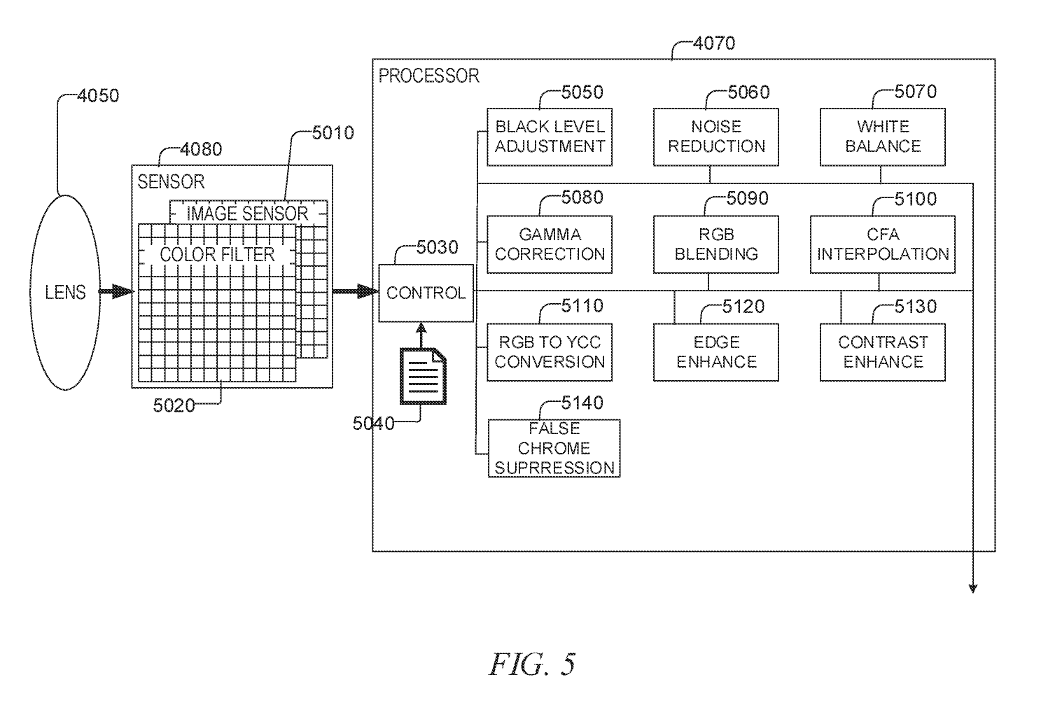

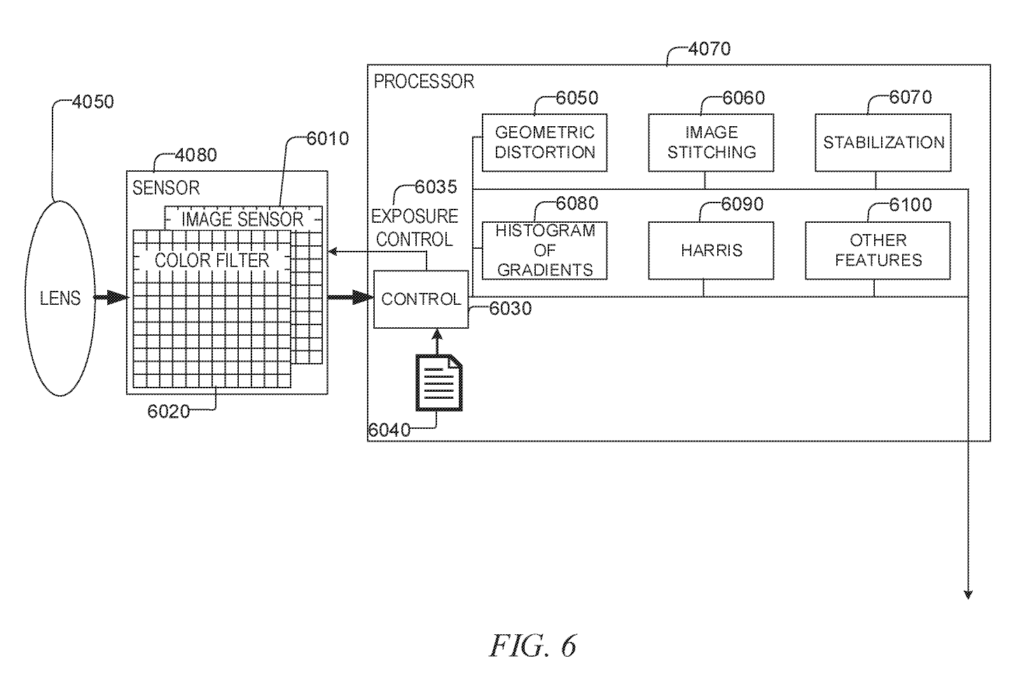

Processor 4070 post-processes the received audio and the received image data from the sensor 4080 in an image pipeline. The image pipeline will be explained with reference to FIGS. 5 and 6. Once the image is processed it may be saved to storage 4120 (e.g., an SDcard, onboard Random Access Memory (RAM). Solid State Drive. or the like). Processor 4070 may communicate with one or more interface controllers 4130. Interface controllers 4130 may control interfaces such as a Universal Serial Bus (USB) interface, a High Definition Multimedia Interface (HDMI), Peripheral Component Interconnect (PCI), and the like.

Processor 4070 may communicate with the display controller 4140 that may control one or more displays 4150. Display 4150 may include liquid crystal displays (LCDs), Light Emitting Diode (LED) displays, Active Matrix Organic Light Emitting Diode (AMOLED) displays, and the like. Display 4150 may display one or more menus, allow for the inputting of one or more commands, allow for changing one or more image capture settings, and the like. Display 4150 may be a touch screen display. Display 4150 along with buttons 4010 may comprise a user interface. In addition, other input and output devices may be provided (e.g., through interface controllers 4130 or other components), such as a mouse, a keyboard, a trackball, or the like.

Digital camera 4000 may be included in, or part of, another device. For example, the digital camera 4000 may be part of a smartphone, tablet, laptop, desktop, or other computer. In these examples, components may be shared across functions. As an example, the processor 4070 may be the central processing unit (CPU) of the computer. Additionally, the layout of the components of FIG. 4 are exemplary and other orderings and layouts are contemplated. In some examples, the components of FIG. 4 may be utilized in the camera of FIG. 1. In these examples, additional components (e.g., additional image sensors and lenses) may be added to support the larger number of lenses and sensors. Additionally, multiple processors and input buttons and output displays may be utilized to support the additional lenses. In other examples, each lens of FIG. 1 may be a separate digital camera 4000 and their outputs may be processed by an image pipeline external from processor 4070.

Turning now to FIG. 5, a block diagram of an example imaging pipeline is shown according to some examples of the present disclosure. Lens 4050 focuses light into the sensor 4080. Sensor 4080 may include an image sensor 5010 (e.g., CCD or CMOS sensor) and a color filter (CFA) 5020. CFA 5020 may be one of the CFAs (3000, 3100, 3200) from FIG. 3. The resulting image data is fed into the processor 4070. There, a control module 5030 reads configuration data 5040. Configuration data 5040 may specify zero or more post processing operations to perform on the data and in what order to perform the operations. Configuration data 5040 may be statically defined (e.g., at manufacturing) or may be configured, e.g., through the buttons 4010, touch screen display (e.g., 4150), or received via one or more external interfaces. Control module 5030 may route the image data to the specified post processing operations in the specified order. Example post processing operations include:
5050 black level adjustments—adjusts for whitening of image dark regions and perceived loss of overall contrast. In some examples, each pixel of the image sensor is tested and the value read from that pixel (each R, G, B value) is then adjusted by a particular value to achieve a uniform result.
5060 noise reduction—these adjustments remove noise in the image by softening the image. For example, by averaging similar neighboring pixels (similar pixels defined by a threshold).
5070 white balance adjustments—these adjustments adjust the relative intensity of RGB values so neutral tones appear neutral. In one example, this may be done by multiplying each R, G, and B value by a different white balance coefficient.
5080 gamma correction—Compensates for nonlinearity of the output device. For example, by applying the transformations:

R′=R^{1/γ}G′=G^{1/γ}B′=B^{1/γ}
5090 RGB blending—Adjust for differences in sensor intensity so that the sensor RGB color space is mapped to a standard RGB color space. In some examples, this may be accomplished for example: (where Mxy is a predetermined constant)

$$[ \begin{matrix}{R}^{′} \\ {G}^{′} \\ {B}^{′}\end{matrix} ] = [ \begin{matrix}{M}_{11} & {M}_{12} & {M}_{13} \\ {M}_{21} & {M}_{22} & {M}_{23} \\ {M}_{31} & {M}_{32} & {M}_{33}\end{matrix} ] [ \begin{matrix}R \\ G \\ B\end{matrix} ]$$

5100 CFA interpolation—Since the CFA only allows one color through per pixel the CFA interpolation aims to interpolate 2 missing colors for each location. For example, by using nearest neighbor interpolation.
5110 RGB to YCC Conversion—separates the luminance component Y from the color components. This is accomplished through the application of a standard formula:

$$( \begin{matrix}Y \\ {C}_{b} \\ {C}_{r}\end{matrix} ) = [ \begin{matrix}0.2989 & 0.5866 & 0.1145 \\ - 0.1687 & - 0.3312 & 0.500 \\ 0.5000 & - 0.4183 & - 0.0816\end{matrix} ] \times ( \begin{matrix}R \\ G \\ B\end{matrix} )$$

5120 Edge Enhancements—applies edge enhancement filters to sharpen the image.
5130 Contrast Enhancements increase or decrease the range between the maximum and minimum pixel intensity in an image.
5140 False Chroma Suppression—this enhancement addresses a problem in CFA interpolation where many of the interpolated images show false colors near the edges of the image. In some examples, median filtering may be used to suppress false chroma.

In one example: a typical pipeline for human vision is: 1. Black level adjustment, 2. Noise reduction, 3. White balance adjustment, 4. CFA interpolation, 5. RGB blending. 6. Gamma Correction, 7. RGB to YCC conversion, 8. Edge Enhancement, 9. Contrast Enhancement, 10. False Chroma Suppression. In other examples, for CV imaging applications, one or more of the above may be bypassed. For example, a pipeline optimized for CV imaging applications may not include noise suppression, color correction and compression blocks.

Turning now to FIG. 6, a block diagram of an example CV optimized imaging pipeline is shown according to some examples of the present disclosure. This image pipeline may be used instead of, or in addition (e.g., the user may select the particular pipeline through the configuration file) to the image pipeline of FIG. 5. Lens 4050 focuses light into the sensor 4080. Sensor 4080 may include an image sensor 6010 and a color filter 6020. Color filter 6020 may be one of the CFAs from FIG. 3, such as 3000, 3100, and 3200.

The resulting image data is fed into the processor 4070. There, a control module 6030 reads configuration data 6040. Control module 6030 may apply a consistent exposure control 6035 to all sensors 4080. Configuration data 6040 may specify zero or more post processing operations to perform on the data and in what order to perform the operations. Configuration data 6040 may be statically defined (e.g., at manufacturing) or may be configured, e.g., through the buttons 4010 or touch screen display (e.g., 4150). Control module 6030 may route the image data to the specified post processing operations in the specified order. Example post processing operations include:
Geometric Distortion compensation 6050—this block may compensate for geometric distortion to objects. In some examples, this may be caused by the curved surface of a multi-lens camera such as the one described with respect to FIG. 1. In some examples this may be accomplished by applying a pre-compensating inverse distortion to the image. In some examples, radial (barrel or fish-eye effects) and tangential distortion may be corrected. For example, using the Brown-Conrady model that corrects for both radial and tangential distortion.
Image Stitching 6060—this block may stitch together images from multiple cameras (e.g., the multi-lens camera described with respect to FIG. 1). For example, key points in each image may be detected, and local invariant descriptors may be extracted from the input images. Then, the descriptors may be matched between the two images. Using a Random Sample Consensus (RANSAC) algorithm, a homography matrix may be created using the matched feature vectors and then a warping transformation may be applied using the homography matrix.
Image Stabilization 6070—this corrects for blurring associated with motion (of either the camera or the captured images) during the exposure. In still photography, image stabilization can be utilized to allow slower shutter speeds (and thus a brighter image) without the attendant blur. This is also useful in video. Example methods include motion estimation and motion compensation.
Histogram of Gradients (HOG) 6080—this block counts occurrences of gradient orientation in localized portions of an image. For example, by computing gradient values (e.g., by applying 1-D centered, point discrete derivative mask in one or both of the horizontal and vertical directions), creating cell histograms (orientation binning), creation of descriptor blocks, block normalization, and then feeding the descriptors into a supervised learning model (e.g., a support vector machine SVM).
Harris & Stephens corner detection 6090 (harris corner)—this block extracts features from the image by detecting corners. This may be computed as a windowed difference of an integral image with a shifted integral image.
Other features 6100 may include one or more other processing blocks—for example, any block from FIG. 5 (e.g., one or more of blocks 5050-5140).

In one example, configuration data 6040 may apply a pipeline of: 1. geometric distortion correction 6050—2. image stitching 6060—3. stabilization 6070. After these are complete, one or more of the histogram of gradients operations 6080. Harris Corner detection 6090, and other features 6100 may also be performed.

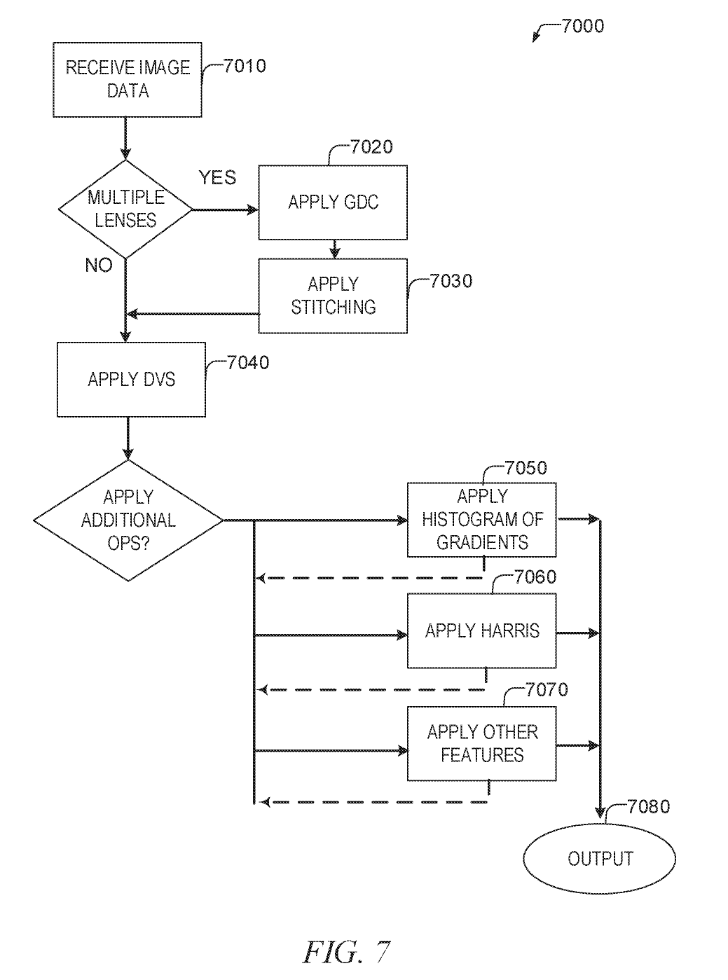

FIG. 7 shows a flowchart of an example method 7000 of the processor performing the image processing pipeline of FIG. 6. At operation 7010 the image data is received. The image data may be in one of many possible formats, for example, one or more (R,G,B) values corresponding to pixels of the sensor. If there are multiple lenses or sensors, the processor may apply geometric distortion compensations at operations 7020 and stitching at operation 7030. In some examples, even if there is a single lens or sensor, the processor may still apply GDC at operation 7020. At operation 7040, image stabilization (DVS) is applied. Additional operations may be applied, alternatively, and in any order, such as Histogram of Gradients at operation 7050, Harris Corner detection at operation 7060, or other features at operation 7070 (such as one or more features from FIG. 5). The output is then produced 7080. Different orders and combinations of operations may be specified by the configuration data.

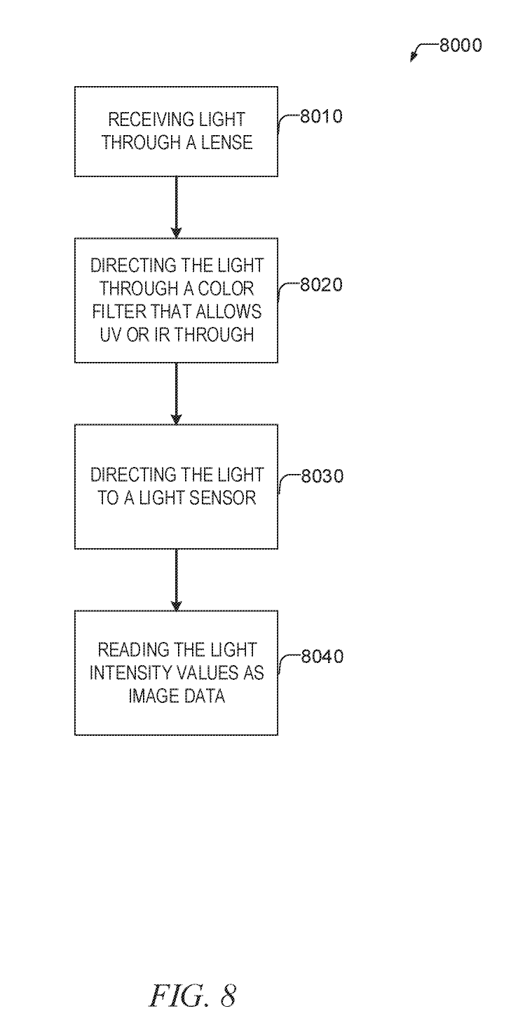

FIG. 8 shows a flowchart of a method 8000 of capturing an image according to some examples of the present disclosure. At operation 8010, the device receives light through one or more lenses. At operation 8020 the light is directed through a CFA that allows one or both of UV and IR through at least one pixel position of the image sensor. For example, a CFA such as 3100 or 3200 of FIG. 3. The filtered light is then directed at operation 8030 to a light sensor such as a CCD or CMOS sensor. In some examples, at operation 8040 the sensor is read for one or more pixels. This sensor data then may be output from the device or post-processed by applying one or more algorithms in a pipeline, such as shown in FIGS. 5 and 6.

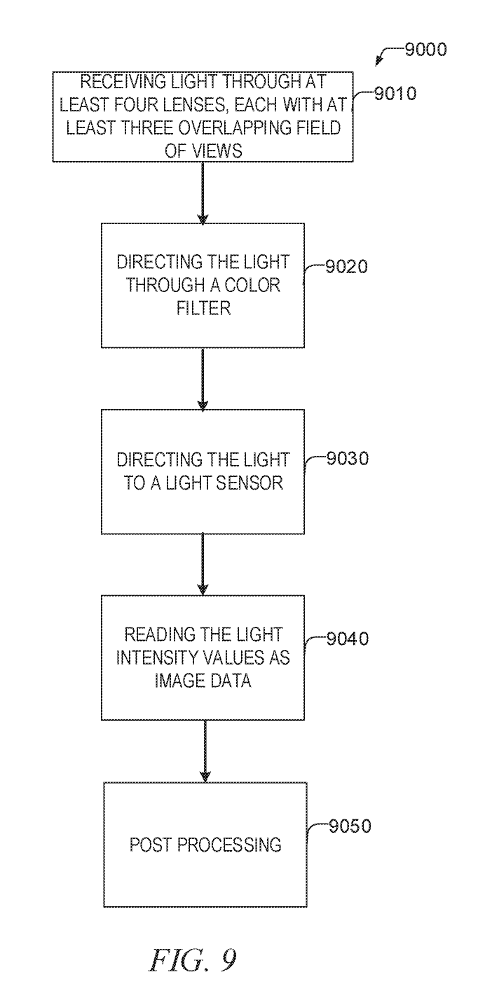

FIG. 9 shows a flowchart of a method 9000 of capturing an image according to some examples of the present disclosure. At operation 9010, the device receives light through at least four lenses, each lens having a field of view at a focal point that at least partially overlaps with a portion of a field of view of at least three other lenses. In some examples, the lenses (and the sensors) may be arranged on a curved surface. At operation 9020 the light may be directed through a CFA, for example, a CFA such as 3000, 3100 or 3200 of FIG. 3. While described herein as using a CFA, in other examples other methods of color separation may be utilized, for example a Foveon X3 sensor, a 3CCD, or the like. The filtered light is then directed at operation 9030 to a light sensor such as a CCD or CMOS sensor. In some examples, light from each lenses is directed to a discrete sensor. In other examples, multiple lenses may focus light upon the same or different portions of a same sensor. In some examples, a single lens may focus light onto multiple sensors. In some examples, at operation 9040 the sensor is read for one or more pixels. This sensor data then may be output from the device or post-processed by applying one or more algorithms in a pipeline at operation 9050, such as shown in FIGS. 5 and 6.

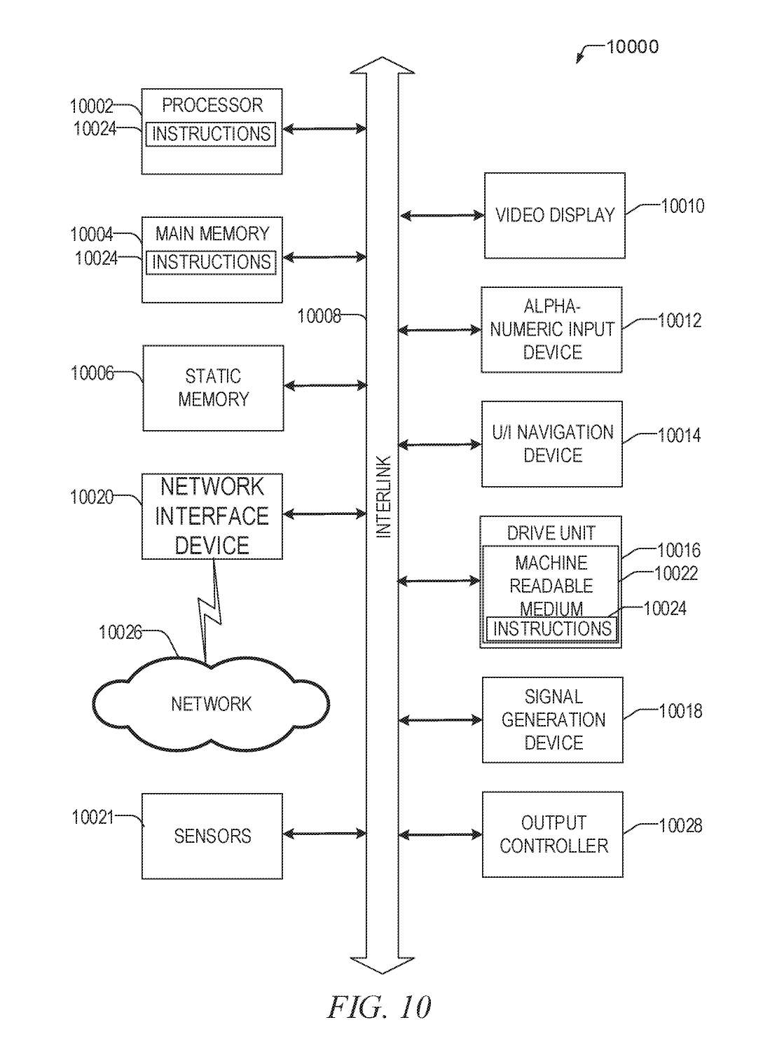

FIG. 10 illustrates a block diagram of an example machine 10000 upon which any one or more of the techniques (e.g., methodologies) discussed herein may perform. In alternative embodiments, the machine 10000 may operate as a standalone device or may be connected (e.g., networked) to other machines. In a networked deployment, the machine 10000 may operate in the capacity of a server machine, a client machine, or both in server-client network environments. In an example, the machine 10000 may act as a peer machine in peer-to-peer (P2P) (or other distributed) network environment. The machine 10000 may be a digital camera (e.g., digital camera 1000, 4000), personal computer (PC), a tablet PC, a set-top box (STB), a personal digital assistant (PDA), a mobile telephone, a smart phone, a web appliance, a network router, switch or bridge, or any machine capable of executing instructions (sequential or otherwise) that specify actions to be taken by that machine. In some examples, the machine 10000 may include the CFAs 3000, 3100, or 3200. In some examples, the machine 10000 may implement the processing pipelines shown in FIG. 5, 6. In some examples, the machine 10000 may implement the methods of FIGS. 8 and 9. Further, while only a single machine is illustrated, the term “machine” shall also be taken to include any collection of machines that individually or jointly execute a set (or multiple sets) of instructions to perform any one or more of the methodologies discussed herein, such as cloud computing, software as a service (SaaS), other computer cluster configurations.

Examples, as described herein, may include, or may operate on, logic or a number of components, modules, or mechanisms. Modules are tangible entities (e.g., hardware) capable of performing specified operations and may be configured or arranged in a certain manner. In an example, circuits may be arranged (e.g., internally or with respect to external entities such as other circuits) in a specified manner as a module. In an example, the whole or part of one or more computer systems (e.g., a standalone, client or server computer system) or one or more hardware processors may be configured by firmware or software (e.g., instructions, an application portion, or an application) as a module that operates to perform specified operations. In an example, the software may reside on a machine readable medium. In an example, the software, when executed by the underlying hardware of the module, causes the hardware to perform the specified operations.

Accordingly, the term “module” is understood to encompass a tangible entity, be that an entity that is physically constructed, specifically configured (e.g., hardwired), or temporarily (e.g., transitorily) configured (e.g., programmed) to operate in a specified manner or to perform part or all of any operation described herein. Considering examples in which modules are temporarily configured, each of the modules need not be instantiated at any one moment in time. For example, where the modules comprise a general-purpose hardware processor configured using software, the general-purpose hardware processor may be configured as respective different modules at different times. Software may accordingly configure a hardware processor, for example, to constitute a particular module at one instance of time and to constitute a different module at a different instance of time.

Machine (e.g., computer system) 10000 may include a hardware processor 10002 (e.g., a central processing unit (CPU), a graphics processing unit (GPU), a hardware processor core, or any combination thereof), a main memory 10004 and a static memory 10006, some or all of which may communicate with each other via an interlink (e.g., bus) 10008. The machine 10000 may further include a display unit 10010, an alphanumeric input device 10012 (e.g., a keyboard), and a user interface (UI) navigation device 10014 (e.g., a mouse). In an example, the display unit 10010, input device 10012 and UI navigation device 10014 may be a touch screen display. The machine 10000 may additionally include a storage device (e.g., drive unit) 10016, a signal generation device 10018 (e.g., a speaker), a network interface device 10020, and one or more sensors 10021, such as a global positioning system (GPS) sensor, compass, accelerometer. CCD. CMOS, or other sensor. The machine 10000 may include an output controller 10028, such as a serial (e.g., universal serial bus (USB), parallel, or other wired or wireless (e.g., infrared (IR), near field communication (NFC), etc.) connection to communicate or control one or more peripheral devices (e.g., a printer, card reader, etc.).

The storage device 10016 may include a machine readable medium 10022 on which is stored one or more sets of data structures or instructions 10024 (e.g., software) embodying or utilized by any one or more of the techniques or functions described herein. The instructions 10024 may also reside, completely or at least partially, within the main memory 10004, within static memory 10006, or within the hardware processor 10002 during execution thereof by the machine 10000. In an example, one or any combination of the hardware processor 10002, the main memory 10004, the static memory 10006, or the storage device 10016 may constitute machine readable media.

While the machine readable medium 10022 is illustrated as a single medium, the term “machine readable medium” may include a single medium or multiple media (e.g., a centralized or distributed database, and/or associated caches and servers) configured to store the one or more instructions 10024.

The term “machine readable medium” may include any medium that is capable of storing, encoding, or carrying instructions for execution by the machine 10000 and that cause the machine 10000 to perform any one or more of the techniques of the present disclosure, or that is capable of storing, encoding or carrying data structures used by or associated with such instructions. Non-limiting machine readable medium examples may include solid-state memories, and optical and magnetic media. Specific examples of machine readable media may include: non-volatile memory, such as semiconductor memory devices (e.g., Electrically Programmable Read-Only Memory (EPROM). Electrically Erasable Programmable Read-Only Memory (EEPROM)) and flash memory devices; magnetic disks, such as internal hard disks and removable disks; magneto-optical disks; Random Access Memory (RAM); Solid State Drives (SSD); and CD-ROM and DVD-ROM disks. In some examples, machine readable media may include non-transitory machine readable media. In some examples, machine readable media may include machine readable media that is not a transitory propagating signal.

The instructions 10024 may further be transmitted or received over a communications network 10026 using a transmission medium via the network interface device 10020. The Machine 10000 may communicate with one or more other machines utilizing any one of a number of transfer protocols (e.g., frame relay, internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), mobile telephone networks (e.g., cellular networks), Plain Old Telephone (POTS) networks, and wireless data networks (e.g., Institute of Electrical and Electronics Engineers (IEEE) 802.11 family of standards known as Wi-Fi®. IEEE 802.16 family of standards known as WiMax®). IEEE 802.15.4 family of standards, a Long Term Evolution (LTE) family of standards, a Universal Mobile Telecommunications System (UMTS) family of standards, peer-to-peer (P2P) networks, among others. In an example, the network interface device 10020 may include one or more physical jacks (e.g., Ethernet, coaxial, or phone jacks) or one or more antennas to connect to the communications network 10026. In an example, the network interface device 10020 may include a plurality of antennas to wirelessly communicate using at least one of single-input multiple-output (SIMO), multiple-input multiple-output (MIMO), or multiple-input single-output (MISO) techniques. In some examples, the network interface device 10020 may wirelessly communicate using Multiple User MIMO techniques.

### Other Notes and Examples

Example 1 is an image capture device, the image capture device comprising: at least four light sensors arranged in at least two columns and two rows on a curved surface, each light sensor overlapping in a respective field of vision of at least three other sensors of the at least four sensors, each sensor converting detected light waves into electrical signals; and a processor, the processor communicatively coupled with the light sensors, the processor to receive the electrical signals and perform the operations comprising: performing post processing on the received electrical signals from each sensor using an image pipeline which transforms the electrical signals into an output image, the image pipeline at least comprising a stitching component to stitch the received electrical signals from the at least four light sensors into a composite image.

In Example 2, the subject matter of Example 1 optionally includes wherein the device comprises ten light sensors arranged in five columns and two rows, wherein each light sensor overlaps in a respective field of vision of at least three other sensors.

In Example 3, the subject matter of Example 2 optionally includes wherein the sensors that are in the middle three columns overlap in a respective field of vision of at least five other sensors.

In Example 4, the subject matter of any one or more of Examples 1-3 optionally include wherein the sensors comprise a color filter array featuring a grid array of elements comprising elements that allow light wavelengths in the red and green and a third wavelength component to reach the sensors, the third wavelength component comprising at least one of: an ultraviolet component or an infrared component.

In Example 5, the subject matter of any one or more of Examples 1-4 optionally include wherein the image processing pipeline excludes operations applying noise suppression, color correction, or compression to create the composite image.

In Example 6, the subject matter of any one or more of Examples 1-5 optionally include wherein the image processing pipeline comprises a geometric distortion correction operation.

In Example 7, the subject matter of any one or more of Examples 1-6 optionally include wherein the image processing pipeline comprises an image stabilization operation.

In Example 8, the subject matter of any one or more of Examples 1-7 optionally include wherein the image processing pipeline comprises a geometric distortion correction operation and an image stabilization operation.

In Example 9, the subject matter of Example 8 optionally includes wherein the image processing pipeline comprises a histogram of gradients.

In Example 10, the subject matter of any one or more of Examples 8-9 optionally include wherein the image processing pipeline comprises a Harris Corner operation.

In Example 11, the subject matter of any one or more of Examples 1-10 optionally include wherein the processor performs a computer vision operation on the composite image.

Example 12 is an image capture method comprising: receiving light through at least four lenses arranged in at least two columns and two rows on a curved surface, each lens overlapping in a respective field of vision of at least three other lenses of the at least four lenses; directing the light through at least one color filter; directing the filter light to at least one sensor that converts the light into electrical signals; and performing post processing on the received electrical signals using an image pipeline which transforms the electrical signals into an output image, the image pipeline at least comprising a stitching component to stitch the received electrical signals from the at least four light sensors into a composite image.

In Example 13, the subject matter of Example 12 optionally includes receiving light through ten lenses arranged in five columns and two rows, wherein each lens overlaps in a respective field of vision of at least three other lenses.

In Example 14, the subject matter of Example 13 optionally includes wherein the lenses that are in the middle three columns overlap in a respective field of vision of at least five other lenses.

In Example 15, the subject matter of any one or more of Examples 12-14 optionally include wherein the color filter array comprises a grid array of elements that allow light wavelengths in the red and green and a third wavelength component to reach the sensors, the third wavelength component comprising at least one of: an ultraviolet component or an infrared component.

In Example 16, the subject matter of any one or more of Examples 12-15 optionally include wherein the image processing pipeline excludes operations applying noise suppression, color correction, or compression to create the composite image.

In Example 17, the subject matter of any one or more of Examples 12-16 optionally include wherein the image processing pipeline comprises a geometric distortion correction operation.

In Example 18, the subject matter of any one or more of Examples 12-17 optionally include wherein the image processing pipeline comprises an image stabilization operation.

In Example 19, the subject matter of any one or more of Examples 12-18 optionally include wherein the image processing pipeline comprises a geometric distortion correction operation and an image stabilization operation.

In Example 20, the subject matter of Example 19 optionally includes wherein the image processing pipeline comprises a histogram of gradients.

In Example 21, the subject matter of any one or more of Examples 19-20 optionally include wherein the image processing pipeline comprises a Harris Corner operation.

In Example 22, the subject matter of any one or more of Examples 12-21 optionally include performing a computer vision operation on the composite image.

Example 23 is an image capture device comprising: means for receiving light through at least four lenses arranged in at least two columns and two rows on a curved surface, each lens overlapping in a respective field of vision of at least three other lenses of the at least four lenses; means for directing the light through at least one color filter; means for directing the filter light to at least one sensor that converts the light into electrical signals; and means for performing post processing on the received electrical signals using an image pipeline which transforms the electrical signals into an output image, the image pipeline at least comprising a stitching component to stitch the received electrical signals from the at least four light sensors into a composite image.

In Example 24, the subject matter of Example 23 optionally includes wherein the device comprises ten lenses arranged in five columns and two rows, wherein each lens overlaps in a respective field of vision of at least three other lenses.

In Example 25, the subject matter of Example 24 optionally includes wherein the lenses that are in the middle three columns overlap in a respective field of vision of at least five other lenses.

In Example 26, the subject matter of any one or more of Examples 23-25 optionally include wherein the color filter array comprises a grid array of elements that allow light wavelengths in the red and green and a third wavelength component to reach the sensors, the third wavelength component comprising at least one of: an ultraviolet component or an infrared component.

In Example 27, the subject matter of any one or more of Examples 23-26 optionally include wherein the image processing pipeline excludes operations applying noise suppression, color correction, or compression to create the composite image.

In Example 28, the subject matter of any one or more of Examples 23-27 optionally include wherein the image processing pipeline comprises means for a geometric distortion correction operation.

In Example 29, the subject matter of any one or more of Examples 23-28 optionally include wherein the image processing pipeline comprises means for an image stabilization operation.

In Example 30, the subject matter of any one or more of Examples 23-29 optionally include wherein the image processing pipeline comprises means for a geometric distortion correction operation and an image stabilization operation.

In Example 31, the subject matter of Example 30 optionally includes wherein the image processing pipeline comprises means for a histogram of gradients.

In Example 32, the subject matter of any one or more of Examples 30-31 optionally include wherein the image processing pipeline comprises means for a Harris Corner operation.

In Example 33, the subject matter of any one or more of Examples 23-32 optionally include means for performing a computer vision operation on the composite image.

Example 34 is an image capture device, the image capture device comprising: a light sensor that converts detect light waves into electrical signals; a color filter array (CFA), the CFA featuring a grid array of elements comprising elements that allow light wavelengths in the red, green, a third, and a fourth wavelength component to reach the sensor, the third wavelength component comprising one of: a blue wavelength component, an ultraviolet component or an infrared component, and the fourth wavelength component comprising one of: an ultraviolet component or an infrared component: and a processor, the processor communicatively coupled with the light sensor, the processor to receive the electrical signals and perform operations comprising: performing post processing on the received electrical signals using an image pipeline which transforms the electrical signals into an output image.

In Example 35, the subject matter of Example 34 optionally includes wherein the fourth wavelength component is an ultraviolet component.

In Example 36, the subject matter of Example 35 optionally includes wherein the grid array of elements is arranged in a series of repeating sets of two rows, wherein a first row of the two rows comprises columns ordered as alternating green and red filters and wherein a second row of the two rows comprises columns ordered as alternating blue and ultraviolet filters.

In Example 37, the subject matter of any one or more of Examples 34-36 optionally include wherein the fourth wavelength component is an infrared component.

In Example 38, the subject matter of Example 37 optionally includes wherein the grid array of elements is arranged in a series of repeating sets of two rows, wherein a first row of the two rows comprises columns ordered as alternating green and red filters and wherein a second row of the two rows comprises columns ordered as alternating blue and infrared filters.

In Example 39, the subject matter of any one or more of Examples 34-38 optionally include wherein the grid array of elements is arranged in a series of repeating sets of two rows, wherein a first row of the two rows comprises columns ordered as alternating green and red filters and wherein a second row of the two rows comprises columns ordered as alternating ultraviolet and infrared filters.

In Example 40, the subject matter of any one or more of Examples 34-39 optionally include wherein the post-processing operations exclude operations that perform noise suppression, color correction, and compression.

In Example 41, the subject matter of any one or more of Examples 34-40 optionally include wherein the post-processing operations comprise geometric distortion correction, image stitching, and image stabilization.

In Example 42, the subject matter of Example 41 optionally includes wherein the post-processing operations comprise performing at least one of a Histogram of Gradients, and a Harris Corner operation.

In Example 43, the subject matter of any one or more of Examples 41-42 optionally include wherein the post-processing operations exclude operations that perform noise suppression, color correction, and compression.

In Example 44, the subject matter of any one or more of Examples 34-43 optionally include wherein the output image is utilized in a computer vision (CV) application.

Example 45 is an image capture method comprising: receiving light through a lense; directing the light through a color filter array (CFA), the CFA featuring a grid array of elements comprising elements that allow light wavelengths in the red, green, a third, and a fourth wavelength component to reach the sensor, the third wavelength component comprising one of: a blue wavelength component, an ultraviolet component or an infrared component, and the fourth wavelength component comprising one of: an ultraviolet component or an infrared component: directing the light passing through the CFA to a light sensor which converts the light to electrical signals; and using a processor, the processor communicatively coupled with the light sensor, to perform post processing on the received electrical signals using an image pipeline which transforms the electrical signals into an output image.

In Example 46, the subject matter of Example 45 optionally includes wherein the fourth wavelength component is an ultraviolet component.

In Example 47, the subject matter of Example 46 optionally includes wherein the grid array of elements is arranged in a series of repeating sets of two rows, wherein a first row of the two rows comprises columns ordered as alternating green and red filters and wherein a second row of the two rows comprises columns ordered as alternating blue and ultraviolet filters.

In Example 48, the subject matter of any one or more of Examples 45-47 optionally include wherein the fourth wavelength component is an infrared component.

In Example 49, the subject matter of Example 48 optionally includes wherein the grid array of elements is arranged in a series of repeating sets of two rows, wherein a first row of the two rows comprises columns ordered as alternating green and red filters and wherein a second row of the two rows comprises columns ordered as alternating blue and infrared filters.

In Example 50, the subject matter of any one or more of Examples 45-49 optionally include wherein the grid array of elements is arranged in a series of repeating sets of two rows, wherein a first row of the two rows comprises columns ordered as alternating green and red filters and wherein a second row of the two rows comprises columns ordered as alternating ultraviolet and infrared filters.

In Example 51, the subject matter of any one or more of Examples 45-50 optionally include wherein the post-processing operations exclude operations that perform noise suppression, color correction, and compression.

In Example 52, the subject matter of any one or more of Examples 45-51 optionally include wherein the post-processing operations comprise geometric distortion correction, image stitching, and image stabilization.

In Example 53, the subject matter of Example 52 optionally includes wherein the post-processing operations comprise performing at least one of a Histogram of Gradients, and a Harris Corner operation.

In Example 54, the subject matter of any one or more of Examples 52-53 optionally include wherein the post-processing operations exclude operations that perform noise suppression, color correction, and compression.

In Example 55, the subject matter of any one or more of Examples 45-54 optionally include wherein the output image is utilized in a computer vision (CV) application.

Example 56 is an image capture device comprising: means for receiving light through a lense; means for directing the light through a color filter array (CFA), the CFA featuring a grid array of elements comprising elements that allow light wavelengths in the red, green, a third, and a fourth wavelength component to reach the sensor, the third wavelength component comprising one of: a blue wavelength component, an ultraviolet component or an infrared component, and the fourth wavelength component comprising one of: an ultraviolet component or an infrared component; means for directing the light passing through the CFA to a light sensor which converts the light to electrical signals; and means for performing post processing on the received electrical signals using an image pipeline which transforms the electrical signals into an output image.

In Example 57, the subject matter of Example 56 optionally includes wherein the fourth wavelength component is an ultraviolet component.

In Example 58, the subject matter of Example 57 optionally includes wherein the grid array of elements is arranged in a series of repeating sets of two rows, wherein a first row of the two rows comprises columns ordered as alternating green and red filters and wherein a second row of the two rows comprises columns ordered as alternating blue and ultraviolet filters.

In Example 59, the subject matter of any one or more of Examples 56-58 optionally include wherein the fourth wavelength component is an infrared component.

In Example 60, the subject matter of Example 59 optionally includes wherein the grid array of elements is arranged in a series of repeating sets of two rows, wherein a first row of the two rows comprises columns ordered as alternating green and red filters and wherein a second row of the two rows comprises columns ordered as alternating blue and infrared filters.

In Example 61, the subject matter of any one or more of Examples 56-60 optionally include wherein the grid array of elements is arranged in a series of repeating sets of two rows, wherein a first row of the two rows comprises columns ordered as alternating green and red filters and wherein a second row of the two rows comprises columns ordered as alternating ultraviolet and infrared filters.

In Example 62, the subject matter of any one or more of Examples 56-61 optionally include wherein the post-processing operations exclude operations that perform noise suppression, color correction, and compression.

In Example 63, the subject matter of any one or more of Examples 56-62 optionally include wherein the post-processing operations comprise means for performing geometric distortion correction, image stitching, and image stabilization.

In Example 64, the subject matter of Example 63 optionally includes wherein the post-processing operations comprise means for performing at least one of a Histogram of Gradients, and a Harris Corner operation.

In Example 65, the subject matter of any one or more of Examples 63-64 optionally include wherein the post-processing operations exclude operations that perform noise suppression, color correction, and compression.

In Example 66, the subject matter of any one or more of Examples 56-65 optionally include wherein the output image is utilized in a computer vision (CV) application.

Example 67 is an image capture device, the image capture device comprising: a light sensor that converts detect light waves into electrical signals; and a processor, the processor communicatively coupled with the light sensor, the processor to receive the electrical signals and perform operations comprising: passing the electrical signals to an image processing pipeline, the image processing pipeline performing at least one image processing operation but excluding operations applying noise suppression, color correction, or compression to create image data.

In Example 68, the subject matter of Example 67 optionally includes wherein the at least one image processing operation comprises a geometric distortion compensation operation.

In Example 69, the subject matter of any one or more of Examples 67-68 optionally include wherein the at least one image processing operation comprises an image stitching operation.

In Example 70, the subject matter of any one or more of Examples 67-69 optionally include wherein the at least one image processing operation comprises a stabilization operation.

In Example 71, the subject matter of any one or more of Examples 67-70 optionally include wherein the at least one image processing operation comprises a geometric distortion compensation operation, and wherein the image processing pipeline further performs an image stitching operation and a stabilization operation.

In Example 72, the subject matter of Example 71 optionally includes wherein the at least one image processing operation comprises a histogram of gradients.

In Example 73, the subject matter of any one or more of Examples 71-72 optionally include wherein the at least one image processing operation comprises a Harris Corner operation.

In Example 74, the subject matter of any one or more of Examples 67-73 optionally include wherein the processor utilizes the image data to perform a computer vision application.

Example 75 is an image capture method, comprising: receiving electrical signals from a light sensor that converts detected light waves into electrical signals; passing the electrical signals to a processor executing an image processing pipeline, the image processing pipeline performing at least one image processing operation but excluding performing operations applying noise suppression, color correction, or compression to create image data; and utilizing the image data to perform a computer vision application.

In Example 76, the subject matter of Example 75 optionally includes wherein the at least one image processing operation comprises a geometric distortion compensation operation.

In Example 77, the subject matter of any one or more of Examples 75-76 optionally include wherein the at least one image processing operation comprises an image stitching operation.

In Example 78, the subject matter of any one or more of Examples 75-77 optionally include wherein the at least one image processing operation comprises a stabilization operation.

In Example 79, the subject matter of any one or more of Examples 75-78 optionally include wherein the at least one image processing operation comprises a geometric distortion compensation operation, and wherein the image processing pipeline further performs an image stitching operation and a stabilization operation.

In Example 80, the subject matter of Example 79 optionally includes wherein the at least one image processing operation comprises a histogram of gradients.

In Example 81, the subject matter of any one or more of Examples 79-80 optionally include wherein the at least one image processing operation comprises a Harris Corner operation.

Example 82 is a machine readable medium comprising instructions, which when performed by a machine, causes the machine to perform operations comprising: receiving electrical signals from a light sensor that converts detected light waves into electrical signals; passing the electrical signals to a processor executing an image processing pipeline, the image processing pipeline performing at least one image processing operation but excluding performing operations applying noise suppression, color correction, or compression to create image data; and utilizing the image data to perform a computer vision application.

In Example 83, the subject matter of Example 82 optionally includes wherein the at least one image processing operation comprises a geometric distortion compensation operation.

In Example 84, the subject matter of any one or more of Examples 82-83 optionally include wherein the at least one image processing operation comprises an image stitching operation.

In Example 85, the subject matter of any one or more of Examples 82-84 optionally include wherein the at least one image processing operation comprises a stabilization operation.

In Example 86, the subject matter of any one or more of Examples 82-85 optionally include wherein the at least one image processing operation comprises a geometric distortion compensation operation, and wherein the image processing pipeline further performs an image stitching operation and a stabilization operation.

In Example 87, the subject matter of Example 86 optionally includes wherein the at least one image processing operation comprises a histogram of gradients.

In Example 88, the subject matter of any one or more of Examples 86-87 optionally include wherein the at least one image processing operation comprises a Harris Corner operation.

Example 89 is an image capture device comprising: means for receiving electrical signals from a light sensor that converts detected light waves into electrical signals; means for passing the electrical signals to a processor executing an image processing pipeline, the image processing pipeline performing at least one image processing operation but excluding performing operations applying noise suppression, color correction, or compression to create image data; and means for utilizing the image data to perform a computer vision application.

In Example 90, the subject matter of Example 89 optionally includes wherein the at least one image processing operation comprises a geometric distortion compensation operation.

In Example 91, the subject matter of any one or more of Examples 89-90 optionally include wherein the at least one image processing operation comprises an image stitching operation.

In Example 92, the subject matter of any one or more of Examples 89-91 optionally include wherein the at least one image processing operation comprises a stabilization operation.

In Example 93, the subject matter of any one or more of Examples 89-92 optionally include wherein the at least one image processing operation comprises a geometric distortion compensation operation, and wherein the image processing pipeline further performs an image stitching operation and a stabilization operation.

In Example 94, the subject matter of Example 93 optionally includes wherein the at least one image processing operation comprises a histogram of gradients.

In Example 95, the subject matter of any one or more of Examples 93-94 optionally include wherein the at least one image processing operation comprises a Harris Corner operation.

What is claimed is:

1. An image capture device, the image capture device comprising:
at least four light sensors arranged in at least two columns and two rows on a curved surface, each light sensor overlapping in a respective field of vision of at least three other sensors of the at least four sensors, each sensor converting detected light waves into electrical signals; and
a processor, the processor communicatively coupled with the light sensors, the processor to receive the electrical signals and perform the operations comprising:
performing post processing on the received electrical signals from each sensor using an image pipeline which transforms the electrical signals into an output image, the image pipeline at least comprising a stitching component to stitch the received electrical signals from the at least four light sensors into a composite image.

2. The image capture device of claim 1, wherein the device comprises ten light sensors arranged in five columns and two rows, wherein each light sensor overlaps in a respective field of vision of at least three other sensors.

3. The image capture device of claim 2, wherein the sensors that are in the middle three columns overlap in a respective field of vision of at least five other sensors.

4. The image capture device of claim 1, wherein the sensors comprise a color filter array featuring a grid array of elements comprising elements that allow light wavelengths in the red and green and a third wavelength component to reach the sensors, the third wavelength component comprising at least one of: an ultraviolet component or an infrared component.

5. The image capture device of claim 1, wherein the image processing pipeline excludes operations applying noise suppression, color correction, or compression to create the composite image.

6. The image capture device of claim 1, wherein the image processing pipeline comprises a geometric distortion correction operation.

7. The image capture device of claim 1, wherein the image processing pipeline comprises an image stabilization operation.

8. The image capture device of claim 1, wherein the image processing pipeline comprises a geometric distortion correction operation and an image stabilization operation.

9. The image capture device of claim 8, wherein the image processing pipeline comprises a histogram of gradients.

10. The image capture device of claim 8, wherein the image processing pipeline comprises a Harris Corner operation.

11. The image capture device of claim 1, wherein the processor performs a computer vision operation on the composite image.

12. An image capture device, the image capture device comprising:
a light sensor that converts detect light waves into electrical signals;
a color filter array (CFA), the CFA featuring a grid array of elements comprising elements that allow light wavelengths in the red, green, a third, and a fourth wavelength component to reach the sensor, the third wavelength component comprising one of: a blue wavelength component, an ultraviolet component or an infrared component, and the fourth wavelength component comprising one of: an ultraviolet component or an infrared component; and
a processor, the processor communicatively coupled with the light sensor, the processor to receive the electrical signals and perform operations comprising:
performing post processing on the received electrical signals using an image pipeline which transforms the electrical signals into an output image.

13. The image capture device of claim 12, wherein the fourth wavelength component is an ultraviolet component.

14. The image capture device of claim 13, wherein the grid array of elements is arranged in a series of repeating sets of two rows, wherein a first row of the two rows comprises columns ordered as alternating green and red filters and wherein a second row of the two rows comprises columns ordered as alternating blue and ultraviolet filters.

15. The image capture device of claim 12, wherein the fourth wavelength component is an infrared component.

16. The image capture device of claim 15, wherein the grid array of elements is arranged in a series of repeating sets of two rows, wherein a first row of the two rows comprises columns ordered as alternating green and red filters and wherein a second row of the two rows comprises columns ordered as alternating blue and infrared filters.

17. The image capture device of claim 12, wherein the grid array of elements is arranged in a series of repeating sets of two rows, wherein a first row of the two rows comprises columns ordered as alternating green and red filters and wherein a second row of the two rows comprises columns ordered as alternating ultraviolet and infrared filters.

18. The image capture device of claim 12, wherein the post-processing operations exclude operations that perform noise suppression, color correction, and compression.

19. The image capture device of claim 12, wherein the post-processing operations comprise geometric distortion correction, image stitching, and image stabilization.

20. The image capture device of claim 19, wherein the post-processing operations comprise performing at least one of a Histogram of Gradients, and a Harris Corner operation.

21. The image capture device of claim 19, wherein the post-processing operations exclude operations that perform noise suppression, color correction, and compression.

22. An image capture device, the image capture device comprising:
a light sensor that converts detect light waves into electrical signals; and
a processor, the processor communicatively coupled with the light sensor, the processor to receive the electrical signals and perform operations comprising:
passing the electrical signals to an image processing pipeline, the image processing pipeline performing at least one image processing operation but excluding operations applying noise suppression, color correction, or compression to create image data.

23. The image capture device of claim 22, wherein the at least one image processing operation comprises a geometric distortion compensation operation, and wherein the image processing pipeline further performs an image stitching operation and a stabilization operation.

24. The image capture device of claim 23 wherein the at least one image processing operation comprises a histogram of gradients.

25. The image capture device of claim 23, wherein the at least one image processing operation comprises a Harris Corner operation.
